(19) United States
(12) Patent Application Publication
(10) Pub. No.: US 2025/0157917 A1
(43) Pub. Date: May 15, 2025

(54) SEMICONDUCTOR DEVICE

(71) Applicant: Renesas Electronics Corporation, Tokyo (JP)

(72) Inventors: Takayuki IGARASHI, Tokyo (JP); Yasutaka NAKASHIBA, Tokyo (JP)

(21) Appl. No.: 18/903,135

(22) Filed: Oct. 1, 2024

(30) Foreign Application Priority Data
Nov. 13, 2023 (JP) 2023-192881

(51) Int. Cl. H01L 23/522; H01L 23/58; H01L 27/06

(52) U.S. Cl. CPC H01L 23/5227; H01L 23/585; H10D 1/20; H10D 84/60

(57) ABSTRACT

A semiconductor device includes a semiconductor substrate, an insulating film, a first coil, a second coil, a third coil, a fourth coil, a first guard ring and a second guard ring. The first coil and the second coil are formed on the semiconductor substrate. The third coil faces the first coil through the insulating film. The fourth coil faces the second coil through the insulating film. The first guard ring is formed to surround the third coil in plan view. The second guard ring is formed to surround the fourth coil in plan view. The first guard ring and the second guard ring are adjacent to each other while being spaced apart from each other in plan view.

### CROSS-REFERENCE TO RELATED APPLICATION

The disclosure of Japanese Patent Application No. 2023-192881 filed on Nov. 13, 2023, including the specification, drawings and abstract is incorporated herein by reference in its entirety.

### BACKGROUND

The present disclosure relates to a semiconductor device.

There is a disclosed technique listed below.
[Patent Document 1] International Patent Application Publication No. WO2014/097425

For example, Patent Document 1 describes a semiconductor device. The semiconductor device described in the Patent Document 1 includes a transformer made of a pair of coils that face each other through an insulating layer.

### SUMMARY

When a transformer included in the semiconductor device described in the Patent Document 1 is used as a high-side transformer and a low-side transformer in order to configure a power conversion device such as a DC-DC (direct current-direct current) converter, a withstand voltage between the high-side transformer and the low-side transformer is insufficient. Other problems and novel features will be apparent from the description of this specification and the accompanying drawings.

A semiconductor device according to the present disclosure includes a semiconductor substrate, an insulating film, a first coil, a second coil, a third coil, and a fourth coil, and a first guard ring and a second guard ring. The first coil and the second coil are formed on the semiconductor substrate. The third coil faces the first coil through the insulating film. The fourth coil faces the second coil through the insulating film. The first guard ring is formed to surround the third coil in plan view. The second guard ring is formed to surround the fourth coil in plan view. The first guard ring and the second guard ring are adjacent to each other while being spaced apart from each other in plan view.

In the semiconductor device according to the present disclosure, a withstand voltage between a transformer made of a first coil and a third coil and a transformer made of a second coil and a fourth coil can be secured.

### BRIEF DESCRIPTIONS OF THE DRAWINGS

FIG. 1 is a block diagram of a semiconductor device DEV1;

FIG. 2 is an explanatory diagram illustrating an example of signal transmission from a control circuit CC to a drive circuit;

FIG. 3 is a first plan view of a semiconductor chip CHP2;

FIG. 4 is a second plan view of the semiconductor chip CHP2;

FIG. 5 is a third plan view of the semiconductor chip CHP2;

FIG. 6 is a cross-sectional view taken along a line VI-VI illustrated in FIG. 5;

FIG. 7 is a cross-sectional view taken along a line VII-VII illustrated in FIG. 5;

FIG. 8 is a plan view of a semiconductor chip CHP2 according to a first modification example;

FIG. 9 is a plan view of a semiconductor chip CHP2 according to a second modification example;

FIG. 10 is a flowchart of manufacturing the semiconductor chip CHP2;

FIG. 11 is a cross-sectional view for explaining an ion implantation step S2;

FIG. 12 is a cross-sectional view for explaining a first-insulating-film formation step S3;

FIG. 13 is a cross-sectional view for explaining a first-via-plug formation step S4;

FIG. 14 is a cross-sectional view for explaining a first-wiring-layer formation step S5;

FIG. 15 is a cross-sectional view for explaining a second-insulating-film formation step S6;

FIG. 16 is a cross-sectional view for explaining a second-via-plug formation step S7;

FIG. 17 is a cross-sectional view for explaining a second-wiring-layer formation step S8;

FIG. 18 is a cross-sectional view for explaining a third-insulating-film formation step S9;

FIG. 19 is a cross-sectional view for explaining a third-via-plug formation step S10;

FIG. 20 is a cross-sectional view for explaining a third-wiring-layer formation step S11;

FIG. 21 is a cross-sectional view for explaining a fourth-wiring-layer formation step S12;

FIG. 22 is a first plan view of a semiconductor chip CHP2 in a semiconductor device DEV2;

FIG. 23 is a second plan view of the semiconductor chip CHP2 in the semiconductor device DEV2;

FIG. 24 is a third plan view of the semiconductor chip CHP2 in the semiconductor device DEV2;

FIG. 25 is a cross-sectional view taken along a line XXV-XXV illustrated in FIG. 22; and

FIG. 26 is a plan view of a semiconductor chip CHP2 in a semiconductor device DEV3.

### DETAILED DESCRIPTION

Details of embodiments of the present disclosure will be described with reference to the drawings. In the drawings described below, the same or corresponding components are denoted by the same reference signs, and overlapping description thereof is not repeated.

### First Embodiment

A semiconductor device according to a first embodiment will be described. The semiconductor device according to the first embodiment is described as a semiconductor device DEV1.

### (Configuration of Semiconductor Device DEV1)

A configuration of the semiconductor device DEV1 will be described below.

### <Schematic Configuration of Semiconductor Device DEV1>

A schematic configuration of the semiconductor device DEV1 will be described below.

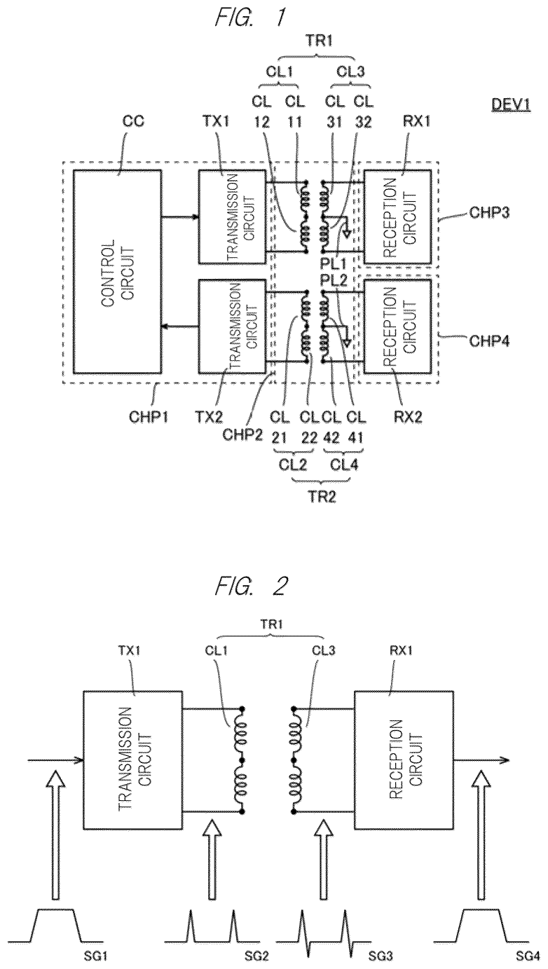

FIG. 1 is a block diagram of the semiconductor device DEV1. As illustrated in FIG. 1, the semiconductor device DEV1 includes a semiconductor chip CHP1, a semiconductor chip CHP2, a semiconductor chip CHP3, and a semiconductor chip CHP4. The semiconductor device DEV1 configures the DC-DC converter. The semiconductor device DEV1 may configure an OBC (On-Board Charger).

The semiconductor chip CHP1 includes a control circuit CC, a transmission circuit TX1, and a transmission circuit TX2. The semiconductor chip CHP3 includes a reception circuit RX1. The semiconductor chip CHP4 includes a reception circuit RX2. The transmission circuit TX1 and the transmission circuit TX2 are electrically connected to the control circuit CC. The reception circuit RX1 and the reception circuit RX2 are electrically connected to a drive circuit not illustrated.

The semiconductor chip CHP2 includes a transformer TR1, a transformer TR2, a lead-out wiring PL1, and a lead-out wiring PL2. The transformer TR1 and the transformer TR2 are respectively a high-side transformer and a low-side transformer.

The transformer TR1 includes a transmission coil CL1 and a reception coil CL3. The transmission coil CL1 includes a coil CL11 and a coil CL12, and the reception coil CL3 includes a coil CL31 and a coil CL32. The transmission coil CL1 and the reception coil CL3 are respectively electrically connected to the transmission circuit TX1 and the reception circuit RX1.

More specifically, one end of the coil CL11 is electrically connected to the transmission circuit TX1, the other end of the coil CL11 is electrically connected to one end of the coil CL12, and the other end of the coil CL12 is electrically connected to the transmission circuit TX1. One end of the coil CL31 is electrically connected to the reception circuit RX1, the other end of the coil CL31 is electrically connected to one end of the coil CL32 via the lead-out wiring PL1, and the other end of the coil CL32 is electrically connected to the reception circuit RX1.

The transformer TR2 includes a transmission coil CL2 and a reception coil CL4. The transmission coil CL2 includes a coil CL21 and a coil CL22, and the reception coil CL4 includes a coil CL41 and a coil CL42. The transmission coil CL2 and the reception coil CL4 are respectively electrically connected to the transmission circuit TX2 and the reception circuit RX2.

More specifically, one end of the coil CL21 is electrically connected to the transmission circuit TX2, the other end of the coil CL21 is electrically connected to one end of the coil CL22, and the other end of the coil CL22 is electrically connected to the transmission circuit TX2. One end of the coil CL41 is electrically connected to the reception circuit RX2, the other end of the coil CL41 is electrically connected to one end of the coil CL42 via the lead-out wiring PL2, and the other end of the coil CL42 is electrically connected to the reception circuit RX2.

In the semiconductor device DEV1, a signal is transmitted from the control circuit CC to the drive circuit by the transmission circuit TX1, the transformer TR1, and the reception circuit RX1. In the semiconductor device DEV1, a signal is also transmitted from the control circuit CC to the drive circuit by the transmission circuit TX2, the transformer TR2, and the reception circuit RX2.

FIG. 2 is an explanatory diagram illustrating an example of signal transmission from the control circuit CC to the drive circuit. As illustrated in FIG. 2, the control circuit CC inputs a signal SG1 to the transmission circuit TX1. The signal SG1 is a square wave. The transmission circuit TX1 modulates the signal SG1 into a signal SG2, and transmits the signal SG2 to the transmission coil CL1. When the signal SG2 flows through the transmission coil CL1, a signal SG3 corresponding to the signal SG2 flows through the reception coil CL3 because of an induced electromotive force. The reception circuit RX1 amplifies the signal SG3 and demodulates the signal SG3 into a signal SG4 (a square wave), and outputs the resultant signal to the drive circuit. The signals are transmitted from the control circuit CC to the drive circuit as described above. Signal transmission using the transmission circuit TX2, the transmission coil CL2, and the reception coil CL4 is also similarly performed. Accordingly, in the semiconductor device DEV1, the signal transmission between the transmission circuit TX1 and the reception circuit RX1 and the signal transmission between the transmission circuit TX2 and the reception circuit RX2 are performed in a pulse communication mode.

### <Detailed Configuration of Semiconductor Chip CHP2>

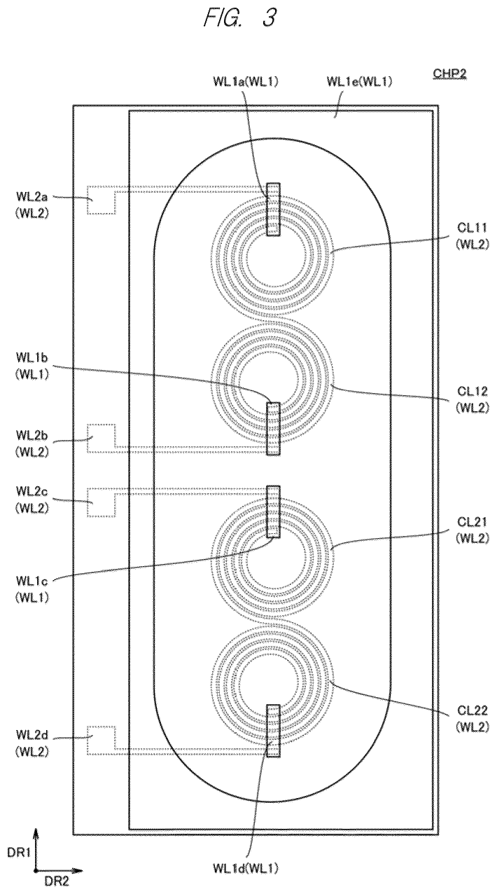

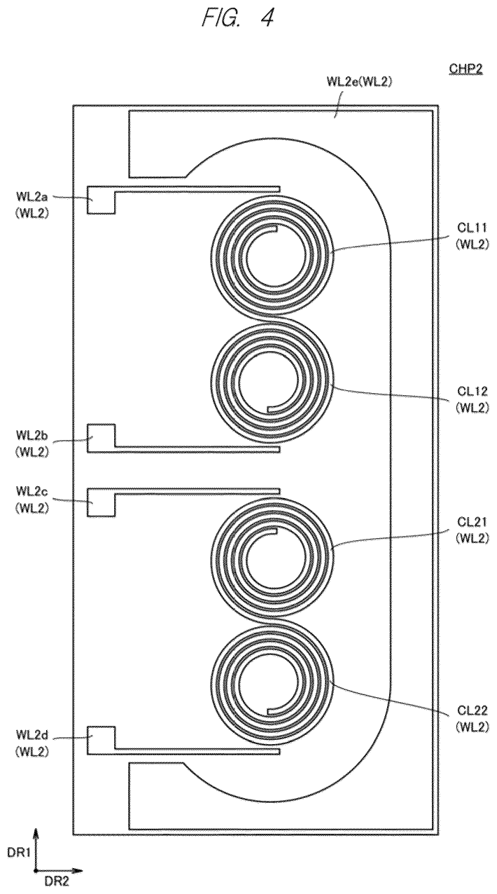

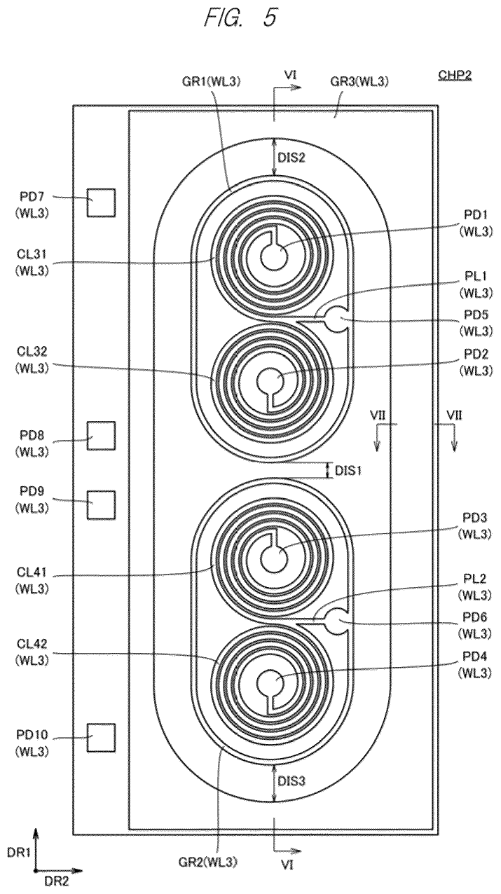

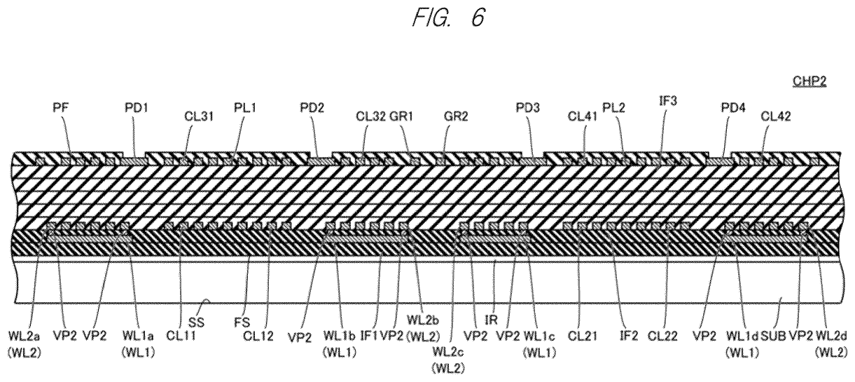

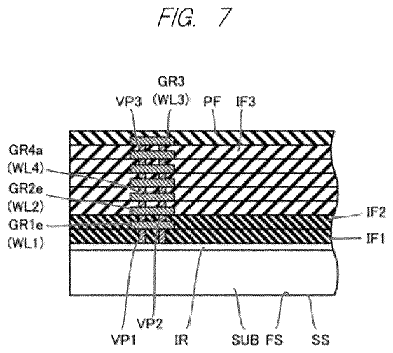

FIG. 3 is a first plan view of the semiconductor chip CHP2. FIG. 4 is a second plan view of the semiconductor chip CHP2. FIG. 5 is a third plan view of the semiconductor chip CHP2. FIG. 6 is a cross-sectional view taken along a line VI-VI illustrated in FIG. 5. FIG. 7 is a cross-sectional view taken along a line VII-VII illustrated in FIG. 5. As illustrated in FIGS. 3 to 7, the semiconductor chip CHP2 includes a semiconductor substrate SUB.

The semiconductor substrate SUB has a first surface FS and a second surface SS. The second surface SS is an opposite surface of the first surface FS. The first surface FS and the second surface SS are each an end surface of the semiconductor substrate SUB in a thickness direction. A material configuring the semiconductor substrate SUB is, for example, single crystal silicon. The semiconductor substrate SUB includes an impurity implantation region IR. The impurity implantation region IR is formed at the first surface FS. A conductivity type of the semiconductor substrate SUB is, for example, a p-type. A dopant concentration in the impurity implantation region IR is higher than a dopant concentration in other regions than the impurity implantation region IR.

The semiconductor chip CHP2 further includes an insulating film IF1. The insulating film IF1 is arranged on the semiconductor substrate SUB. More specifically, the insulating film IF1 is arranged on the first surface FS. A material configuring the insulating film IF1 is, for example, a silicon oxide.

The semiconductor chip CHP2 further includes a wiring layer WL1. The wiring layer WL1 is arranged on the insulating film IF1. The wiring layer WL1 includes a wiring WL1a, a wiring WL1b, a wiring WL1c, and a wiring WL1d. The wiring WL1a, the wiring WL1b, the wiring WL1c, and the wiring WL1d extend in a first direction DR1 in plan view. A material configuring the wiring layer WL1 is, for example, a conductive material containing aluminum as a main component.

The wiring layer WL1 further includes a wiring WL1e. The wiring WL1e overlaps a guard ring GR3 described later in plan view although not illustrated. The semiconductor chip CHP2 further includes a via-plug VP1. The via-plug VP1 is embedded in a via hole formed in the insulating film IF1, and connects the wiring WL1e and the semiconductor substrate SUB (the impurity implantation region IR) to each other. A material configuring the via-plug VP1 is, for example, a conductive material containing tungsten as a main component.

The semiconductor chip CHP2 further includes an insulating film IF2. The insulating film IF2 is arranged on the insulating film IF1 to cover the wiring layer WL1. A material configuring the insulating film IF2 is, for example, a silicon oxide.

The semiconductor chip CHP2 further includes a wiring layer WL2. The wiring layer WL2 is arranged on the insulating film IF2. The wiring layer WL2 includes a transmission coil CL1 (a coil CL11 and a coil CL12), a transmission coil CL2 (a coil CL21 and a coil CL22), a wiring WL2a, a wiring WL2b, a wiring WL2c, and a wiring WL2d. A material configuring the wiring layer WL2 is, for example, a conductive material containing aluminum as a main component.

The coil CL11 and the coil CL12 are adjacent to each other in the first direction DR1. The coil CL11 and the coil CL12 are spirally wound in plan view. More specifically, in an example illustrated in FIG. 4, the coil CL11 is wound counterclockwise in a direction from its innermost periphery toward its outermost periphery in plan view, and the coil CL12 is spirally wound clockwise in a direction from its outermost periphery toward its innermost periphery in plan view. The coil CL11 and the coil CL12 are electrically connected in series with each other. More specifically, an end of an outermost periphery of the coil CL11 is connected to an end of an outermost periphery of the coil CL12.

The coil CL21 and the coil CL22 are adjacent to each other in the first direction DR1. The coil CL21 and the coil CL22 are spirally wound in plan view. More specifically, in the example illustrated in FIG. 4, the coil CL21 is wound counterclockwise in a direction from its innermost periphery toward its outermost periphery in plan view, and the coil CL22 is spirally wound clockwise in a direction from its outermost periphery toward its innermost periphery in plan view. The coil CL21 and the coil CL22 are electrically connected in series with each other. More specifically, an end of an outermost periphery of the coil CL21 is connected to an end of an outermost periphery of the coil CL22.

The transmission coil CL1 and the transmission coil CL2 are adjacent to each other while being spaced apart from each other in the first direction DR1. More specifically, the coil CL12 is adjacent to the coil CL21 in the first direction DR1.

The wiring WL2a, the wiring WL2b, the wiring WL2c, and the wiring WL2d extend in a second direction DR2 in plan view. The second direction DR2 is a direction perpendicular to the first direction DR1 in plan view. One end of the wiring WL2a and one end of the wiring WL2b are respectively adjacent to the coil CL11 and the coil CL12. One end of the wiring WL2c and one end of the wiring WL2d are respectively adjacent to the coil CL21 and the coil CL22.

The wiring layer WL2 further includes a wiring WL2e. The wiring WL2e surrounds the transmission coil CL1 and the transmission coil CL2 in plan view, and overlaps a guard ring GR3 described later. However, the wiring WL2e does not completely surround the transmission coils CL1 and CL2, but is partially separated. The semiconductor chip CHP2 further includes a via-plug VP2. The via-plug VP2 is embedded in a via hole formed in the insulating film IF2, and connects the wiring WL1e and the wiring WL2e to each other. A material configuring the via-plug VP2 is, for example, a conductive material containing tungsten as a main component.

The wiring WL1a is connected to the wiring WL2a and the coil CL11 by the via-plug VP2. The wiring WL1b is connected to the wiring WL2b and the coil CL12 by the via-plug VP2. The wiring WL1c is connected to the wiring WL2c and the coil CL21 by the via-plug VP2. The wiring WL1d is connected to the wiring WL2d and the coil CL22 by the via-plug VP2. A material configuring the via-plug VP2 is, for example, a conductive material containing tungsten as a main component.

The semiconductor chip CHP2 further includes a plurality of insulating films IF3. The plurality of insulating films IF3 are stacked. The insulating film IF3 as the lowermost layer is arranged on the insulating film IF2 to cover the wiring layer WL2. A material configuring the insulating film IF3 is, for example, a silicon oxide.

The semiconductor chip CHP2 further includes a wiring layer WL3. The wiring layer WL3 includes a reception coil CL3 (a coil CL31 and a coil CL32), a reception coil CL4 (a coil CL41 and a coil CL42), a lead-out wiring PL1, a lead-out wiring PL2, a guard ring GR1, a guard ring GR2, and the guard ring GR3. A material configuring the wiring layer WL3 is, for example, a conductive material containing aluminum as a main component.

The coil CL31 and the coil CL32 are adjacent to each other in the first direction DR1. The coil CL31 and the coil CL32 are spirally wound in plan view. More specifically, in an example illustrated in FIG. 5, the coil CL31 is wound counterclockwise in a direction from its innermost periphery toward its outermost periphery in plan view, and the coil CL32 is spirally wound clockwise in a direction from its outermost periphery toward its innermost periphery in plan view. The coil CL31 and the coil CL32 are electrically connected in series with each other through the lead-out wiring PL1. More specifically, an end of an outermost periphery of the coil CL31 is connected to an end of an outermost periphery of the coil CL32.

The coil CL31 and the coil CL32 respectively face the coil CL11 and the coil CL12 through insulating films (the plurality of insulating films IF3). As a result, the coil CL31 and the coil CL32 are respectively magnetically coupled to the coil CL11 and the coil CL12.

The coil CL41 and the coil CL42 are adjacent to each other in the first direction DR1. The coil CL41 and the coil CL42 are spirally wound in plan view. More specifically, in the example illustrated in FIG. 5, the coil CL41 is wound counterclockwise in a direction from its innermost periphery toward its outermost periphery in plan view, and the coil CL42 is spirally wound clockwise in a direction from its outermost periphery toward its innermost periphery in plan view. The coil CL41 and the coil CL42 are electrically connected in series with each other through the lead-out wiring PL2. More specifically, an end of an outermost periphery of the coil CL41 is connected to an end of an outermost periphery of the coil CL42.

The coil CL41 and the coil CL42 respectively face the coil CL21 and the coil CL22 through insulating films (the plurality of insulating films IF3). As a result, the coil CL41 and the coil CL42 are respectively magnetically coupled to the coil CL21 and the coil CL22. As described above, the coil CL12 and the coil CL21 are spaced apart from each other in the first direction DR1, and therefore, the coil CL32 and the coil CL41 are also spaced apart from each other in the first direction DR1.

The guard ring GR surrounds the reception coil CL3 in plan view. The guard ring GR2 surrounds the reception coil CL4 in plan view. The guard ring GR2 is adjacent to the guard ring GR1 in the first direction DR1 while being spaced apart from the guard ring GR1. The guard ring GR3 surrounds the guard ring GR1 and the guard ring GR2 in plan view. A first potential is applied to the guard ring GR1. A second potential is applied to the guard ring GR2. A third potential is applied to the guard ring GR3. The first potential and the second potential are higher than the third potential. The first potential is higher than the second potential. The guard ring GR1, the guard ring GR2, and the guard ring GR3 each have, for example, an oval shape in plan view.

A shortest distance between the guard ring GR1 and the guard ring GR2 in plan view is set as a distance DIS1. A shortest distance between the guard ring GR1 and the guard ring GR3 in plan view is set as a distance DIS2. A shortest distance between the guard ring GR2 and the guard ring GR3 in plan view is set as a distance DIS3. Since the guard ring GR1 and the guard ring GR2 are spaced apart from each other as described above, the distance DIS1 is larger than zero. The distance DIS1 is preferably equal to or smaller than the distance DIS2 and the distance DIS3. That is, a relationship of “0<DIS1≤DIS2” and a relationship of “0<DIS1≤DIS3” are preferably satisfied among the distance DIS1, the distance DIS2, and the distance DIS3. The distance DIS1 is preferably equal to or larger than 15 μm. The distance DIS2 and the distance DIS3 are each preferably equal to or larger than 150 μm.

The wiring layer WL3 further includes a pad PD1, a pad PD2, a pad PD3, a pad PD4, a pad PD5, and a pad PD6. The pad PD1 and the pad PD2 are respectively connected to an end of an innermost periphery of the coil CL31 and an end of an innermost periphery of the coil CL32. The pad PD3 and the pad PD4 are respectively connected to an end of an innermost periphery of the coil CL41 and an end of an innermost periphery of the coil CL42. The pad PD5 and the pad PD6 are respectively connected to the lead-out wiring PL1 and the lead-out wiring PL2. The pad PD5 is also connected to the guard ring GR1, and the pad PD6 is also connected to the guard ring GR2.

The wiring layer WL3 further includes a pad PD7, a pad PD8, a pad PD9, and a pad PD10. The pad PD7, the pad PD8, the pad PD9, and the pad PD10 are arranged outside the guard ring GR3 in plan view. The pad PD7 and the pad PD8 respectively overlap the other end of the wiring WL2a and the other end of the wiring WL2b in plan view. The pad PD9 and the pad PD10 respectively overlap the other end of the wiring WL2c and the other end of the wiring WL2d in plan view.

The semiconductor chip CHP2 further includes a plurality of wiring layers WL4. Each of the plurality of wiring layers WL4 is arranged on one insulating film IF3, and is covered with the other one insulating film IF3 arranged on the one insulating film IF3. However, the wiring layer WL4 as the lowermost layer is arranged on the insulating film IF2, and is covered with the insulating film IF3 as the lowermost layer. Each of the plurality of wiring layers WL4 includes a wiring WL4a. The wiring WL4a overlaps the guard ring GR3 in plan view, although not illustrated.

The semiconductor chip CHP2 further includes a plurality of via-plugs VP3. The plurality of via-plugs VP3 are respectively embedded in via holes formed in the plurality of insulating films IF3. The via-plugs VP3 respectively connect the two wirings WL4a that overlap each other through the insulating film IF3, connect the wiring WL4a as the uppermost layer and the guard ring GR3, and connect the wiring WL4a as the lowermost layer and the wiring WL2e to each other.

The pad PD7, the pad PD8, the pad PD9, and the pad PD10 are respectively electrically connected to the other end of the wiring WL2a, the other end of the wiring WL2b, the other end of the wiring WL2c, and the other end of the wiring WL2d by the via-plug VP3 and the plurality of wiring layers WL4, although not illustrated. Accordingly, the pad PD7, the pad PD8, the pad PD9, and the pad PD10 are respectively electrically connected to the coil CL11, the coil CL12, the coil CL21, and the coil CL22.

The semiconductor chip CHP2 further includes a passivation film PF. The passivation film PF is arranged on the insulating film IF3 as the uppermost layer to cover the wiring layer WL3. The pad PD1, the pad PD2, the pad PD3, the pad PD4, the pad PD5, the pad PD6, the pad PD7, the pad PD8, the pad PD9, and the pad PD10 are exposed from an opening of the passivation film PF. A material configuring the passivation film PF is, for example, a silicon nitride. The pad PD1, the pad PD2, the pad PD3, the pad PD4, the pad PD5, the pad PD6, the pad PD7, the pad PD8, the pad PD9, and the pad PD10 are each used as a bonding pad for external connection.

### <Modification Example of Semiconductor Chip CHP2>

A modification example of the semiconductor chip CHP2 will be described below.

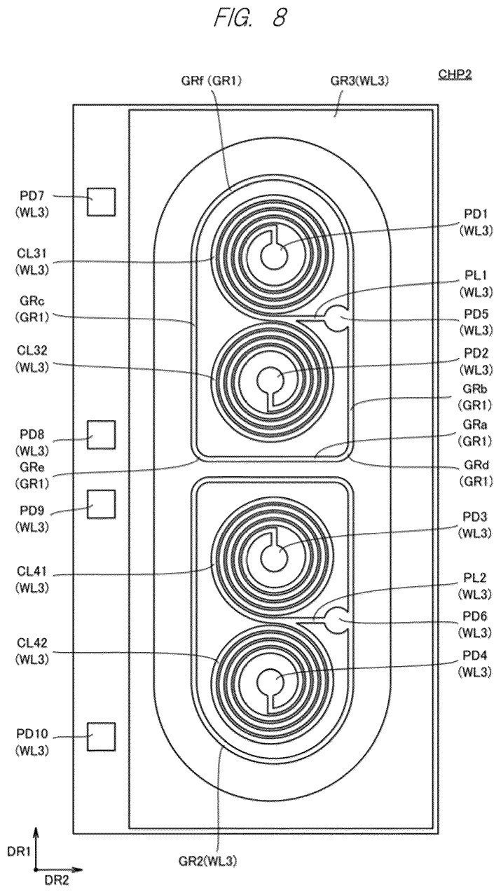

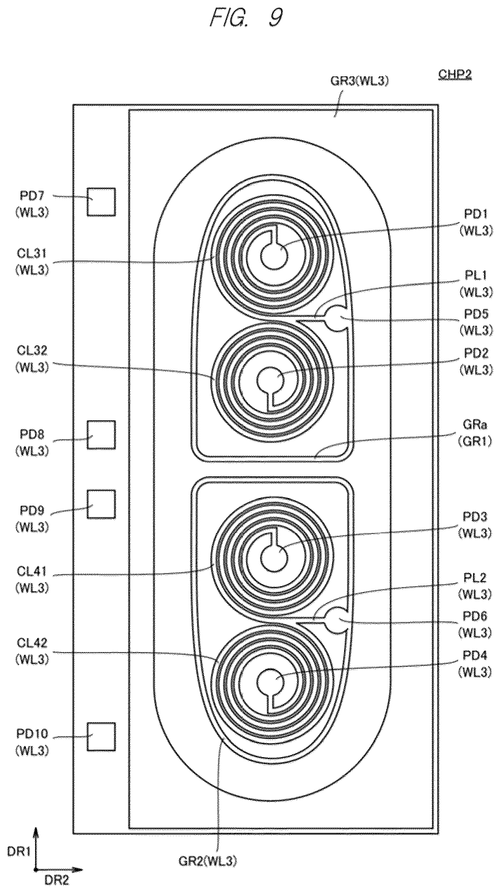

FIG. 8 is a plan view of a semiconductor chip CHP2 according to a first modification example. As illustrated in FIG. 8, each of the guard ring GR1 and the guard ring GR2 may has a straight-line portion GRa. The straight-line portion GRa extends in a second direction DR2 in plan view. The second direction DR2 is a direction perpendicular to the first direction DR1 in plan view. The straight-line portion GRa of the guard ring GR1 and the straight-line portion GRa of the guard ring GR2 face each other in the first direction DR1. In the first direction DR1, a length of the straight-line portion GRa is preferably larger than a width of the reception coil CL3 (coil CL31 and coil CL32) and a width of the reception coil CL4 (coil CL41 and coil CL42). A length of the straight-line portion GRa in the second direction DR2 may be, for example, equal to or larger than 50 μm.

Each of the guard ring GR1 and the guard ring GR2 may further has a straight-line portion GRb, a straight-line portion GRc, a corner portion GRd, a corner portion GRe, and a circular arc portion GRf. The straight-line portion GRb and the straight-line portion GRc extend in the first direction DR1, and face each other in the second direction DR2. One end of the straight-line portion GRb is connected to one end of the straight-line portion GRa by the corner portion GRd. One end of the straight-line portion GRc is connected to the other end of the straight-line portion GRa by the corner portion GRe. The corner portion GRd and the corner portion GRe extend in a curved shape having a predetermined curvature in plan view. The circular arc portion GRf connects the other end of the straight-line portion GRb and the other end of the straight-line portion GRc to each other. The circular arc portion GRf has a circular arc shape in plan view.

FIG. 9 is a plan view of a semiconductor chip CHP2 according to a second modification example. As illustrated in FIG. 9, each of the guard ring GR1 and the guard ring GR2 does not need to include the straight-line portion GRb, the straight-line portion GRc, the corner portion GRd, the corner portion GRe, and the circular arc portion GRf. In this case, a remaining portion of each of the guard ring GR1 and the guard ring GR2 may extend while being curved from one end to the other end of the straight-line portion GRa. From another viewpoint, the remaining portion of each of the guard ring GR1 and the guard ring GR2 may have a wedge shape in plan view.

### <Method of Manufacturing Semiconductor Chip CHP2>

A method of manufacturing the semiconductor chip CHP2 will be described below.

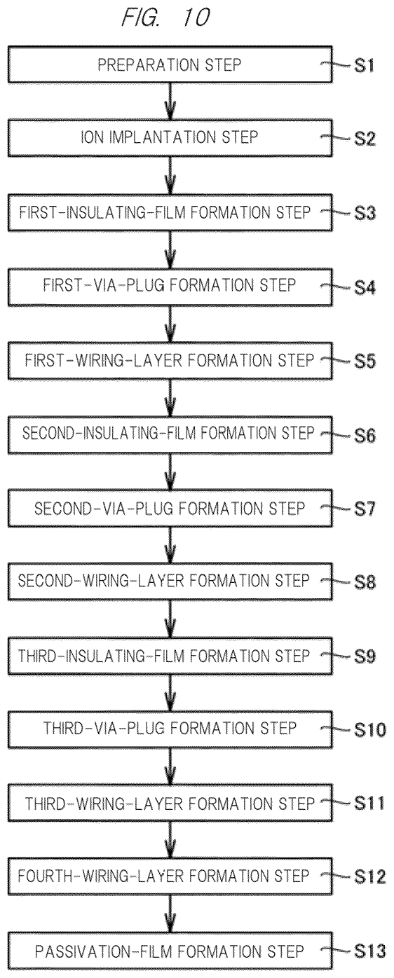

FIG. 10 is a flowchart of manufacturing the semiconductor chip CHP2. As illustrated in FIG. 10, the method of manufacturing the semiconductor chip CHP2 includes a preparation step S1, an ion implantation step S2, a first-insulating-film formation step S3, a first-via-plug formation step S4, a first-wiring-layer formation step S5, and a second-insulating-film formation step S6. The method of manufacturing the semiconductor chip CHP2 further includes a second-via-plug formation step S7, a second-wiring-layer formation step S8, a third-insulating-film formation step S9, a third-via-plug formation step S10, a third-wiring-layer formation step S11, a fourth-wiring-layer formation step S12, and a passivation-film formation step S13.

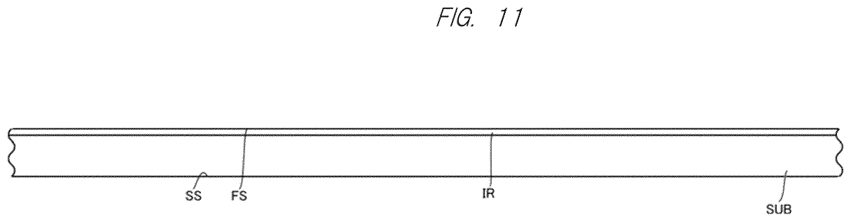

In the preparation step S1, the semiconductor substrate SUB is prepared. After the preparation step S1, the ion implantation step S2 is performed. FIG. 11 is a cross-sectional view for explaining the ion implantation step S2. As illustrated in FIG. 11, when the ion implantation is performed in the ion implantation step S2, the impurity implantation region IR is formed. After the ion implantation step S2, the first-insulating-film formation step S3 is performed.

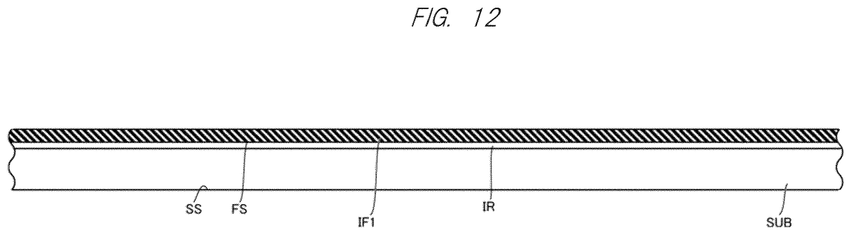

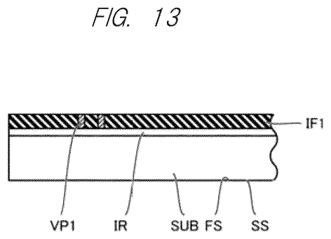

FIG. 12 is a cross-sectional view for explaining the first-insulating-film formation step S3. As illustrated in FIG. 12, in the first-insulating-film formation step S3, the insulating film IF1 is formed on the semiconductor substrate SUB by, for example, a CVD (Chemical Vapor Deposition) method. After the first-insulating-film formation step S3, the first-via-plug formation step S4 is performed.

FIG. 13 is a cross-sectional view for explaining the first-via-plug formation step S4. As illustrated in FIG. 13, in the first-via-plug formation step S4, the via-plug VP1 is embedded in the insulating film IF1. In the first-via-plug formation step S4, firstly, a via hole is formed in the insulating film IF1 by dry etching using a resist pattern formed by a photolithography method as a mask. Secondly, a material configuring the via-plug VP1 is embedded in the via hole by, for example, a CVD method. Thirdly, a material configuring the via-plug VP1, which protrudes from the via hole, is removed by, for example, a CMP (Chemical Mechanical Polishing) method. After the first-via-plug formation step S4, the first-wiring-layer formation step S5 is performed.

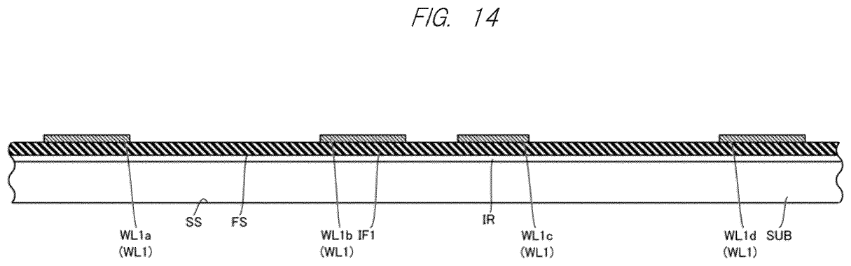

FIG. 14 is a cross-sectional view for explaining the first-wiring-layer formation step S5. As illustrated in FIG. 14, in the first-wiring-layer formation step S5, the wiring layer WL1 is formed on the insulating film IF1. In the first-wiring-layer formation step S5, firstly, a material configuring the wiring layer WL1 is formed by, for example, a sputtering method. Secondly, the material configuring the formed wiring layer WL1 is patterned by, for example, dry etching using a resist pattern formed by a photolithography method as a mask. After the first-wiring-layer formation step S5, the second-insulating-film formation step S6 is performed.

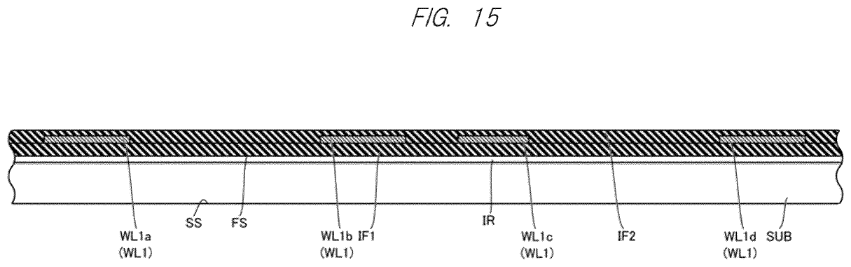

FIG. 15 is a cross-sectional view for explaining the second-insulating-film formation step S6. As illustrated in FIG. 15, in the second-insulating-film formation step S6, the insulating film IF2 is formed on the insulating film IF1 to cover the wiring layer WL1. In the second-insulating-film formation step S6, firstly, a material configuring the insulating film IF2 is formed by, for example, a CVD method. Secondly, the material configuring the formed insulating film IF2 is flattened by, for example, a CMP method. After the second-insulating-film formation step S6, the second-via-plug formation step S7 is performed.

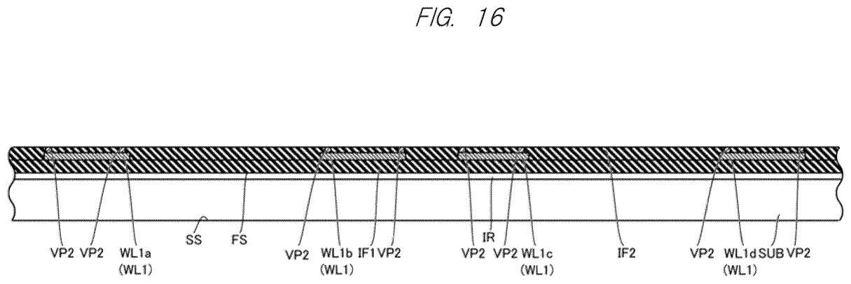

FIG. 16 is a cross-sectional view for explaining the second-via-plug formation step S7. As illustrated in FIG. 16, in the second-via-plug formation step S7, the via-plug VP2 is embedded in the insulating film IF2 by a similar method to that in the first-via-plug formation step S4. After the second-via-plug formation step S7, the second-wiring-layer formation step S8 is performed.

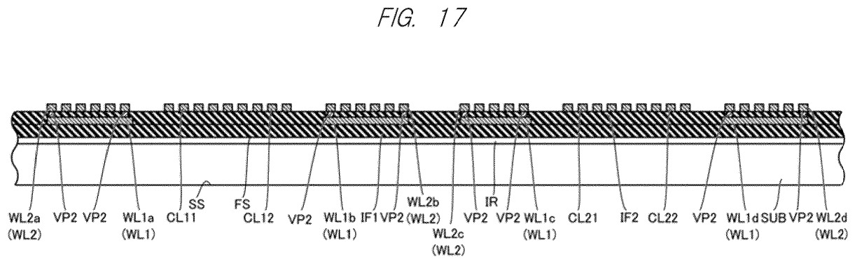

FIG. 17 is a cross-sectional view for explaining the second-wiring-layer formation step S8. As illustrated in FIG. 17, in the second-wiring-layer formation step S8, the wiring layer WL2 is formed on the insulating film IF2. In the second-wiring-layer formation step S8, firstly, a material configuring the wiring layer WL2 is formed by, for example, sputtering. Secondly, the material configuring the formed wiring layer WL2 is patterned by, for example, dry etching using a resist pattern formed by a photolithography method as a mask. After the second-wiring-layer formation step S8, the third-insulating-film formation step S9 is performed.

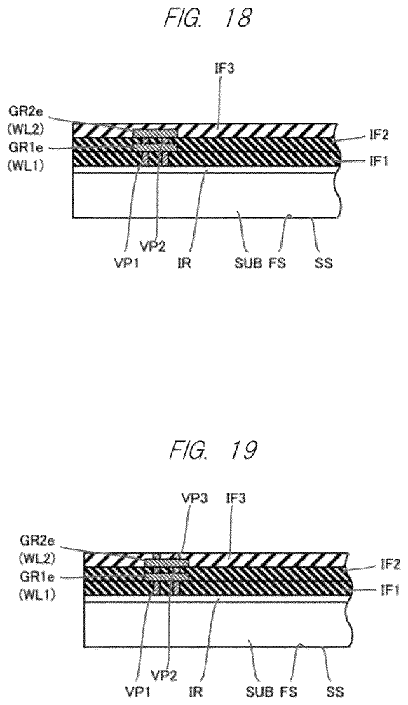

FIG. 18 is a cross-sectional view for explaining the third-insulating-film formation step S9. As illustrated in FIG. 18, in the third-insulating-film formation step S9, the insulating film IF3 is formed on the insulating film IF2 to cover the wiring layer WL2. After the third-insulating-film formation step S9, the third-via-plug formation step S10 is performed.

FIG. 19 is a cross-sectional view for explaining the third-via-plug formation step S10. As illustrated in FIG. 19, in the third-via-plug formation step S10, the via-plug VP3 is embedded in the insulating film IF3 by a similar method to that in the second-via-plug formation step S7. After the third-via-plug formation step S10, the third-wiring-layer formation step S11 is performed.

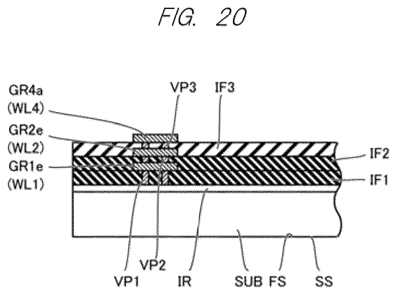

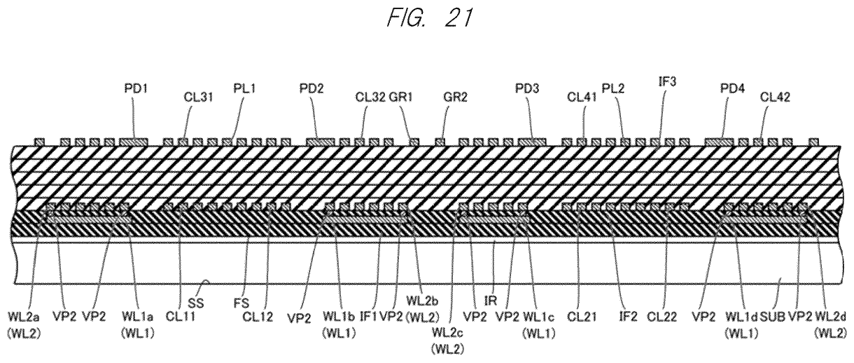

FIG. 20 is a cross-sectional view for explaining the third-wiring-layer formation step S11. As illustrated in FIG. 20, in the third-wiring-layer formation step S11, the wiring layer WL4 is formed by a similar method to that in the second-wiring-layer formation step S8. Until the insulating film IF3 as the uppermost layer is formed, the third-insulating-film formation step S9, the third-via-plug formation step S10, and the third-wiring-layer formation step S11 are repeated. After the insulating film IF3 as the uppermost layer is formed, the fourth-wiring-layer formation step S12 is performed.

FIG. 21 is a cross-sectional view for explaining the fourth-wiring-layer formation step S12. As illustrated in FIG. 21, in the fourth-wiring-layer formation step S12, the wiring layer WL3 is formed on the insulating film IF3 as the uppermost layer by a similar method to that in the second-wiring-layer formation step S8. After the fourth-wiring-layer formation step S12, the passivation-film formation step S13 is performed.

In the passivation-film formation step S13, the passivation film PF is formed on the insulating film IF3 as the uppermost layer to cover the wiring layer WL4. In the passivation-film formation step S13, firstly, a material configuring the passivation film PF is formed by, for example, a CVD method. Secondly, the material configuring the passivation film PF is patterned by, for example, dry etching using a resist pattern formed by a photolithography method as a mask.

When division into pieces is performed by dicing or the like after the foregoing steps, a structure of the semiconductor chip CHP2 illustrated in FIGS. 3 to 7 is formed.

### <Effect of Semiconductor Device DEV1>

An effect of the semiconductor device DEV1 will be described below.

In the semiconductor device DEV1, the transformer TR1 and the transformer TR2 respectively function as a high-side transformer and a low-side transformer. Accordingly, a withstand voltage between the transformer TR1 and the transformer TR2 needs to be secured.

In the semiconductor chip CHP2, the reception coil CL3 (the coil CL31 and the coil CL32) is surrounded by the guard ring GR1 in plan view, and the reception coil CL4 (the coil CL41 and the coil CL42) is surrounded by the guard ring GR2 in plan view. Accordingly, in the semiconductor chip CHP2, a potential difference between the reception coils CL3 and CL4 and their peripheries (specifically, a potential difference between the reception coils CL3 and CL4 and the guard ring GR3) is stabilized. Thus, according to the semiconductor device DEV1 including the semiconductor chip CHP2, a withstand voltage between the transformer TR1 and the transformer TR2 can be secured.

A problem between the reception coils CL3 and CL4 and the guard ring GR3 (between the guard rings GR1 and GR2 and the guard ring GR3) is a withstand voltage against an alternating current, and the distance DIS2 and the distance DIS3 are set to satisfy the withstand voltage. A problem between the reception coil CL3 and the reception coil CL4 (between the guard ring GR1 and the guard ring GR2) is a withstand voltage against a direct current, and the withstand voltage can be secured even if the distance DIS1 is smaller than the distance DIS2 and the distance DIS3. Accordingly, when a relationship of “0<Distance DIS1≤Distance DIS2” and a relationship of “0<Distance DIS1≤Distance DIS3” are satisfied, the semiconductor chip CHP2 can be downsized while the desired withstand voltage can be secured.

When each of the guard ring GR1 and the guard ring GR2 includes the straight-line portion GRa, it is difficult to form a singular point at which an electric field is concentrated between the guard ring GR1 and the guard ring GR2. Accordingly, in this case, even if the distance DIS1 is small, the withstand voltage between the guard ring GR1 and the guard ring GR2 (between the reception coil CL3 and the reception coil CL4) can be increased, and thus, the semiconductor chip CHP2 can be downsized.

In the semiconductor device DEV1, a distance between the transmission coil CL2 and the reception coil CL4 is larger than that in a semiconductor device DEV2 described later. This means that a capacitance caused by the transmission coil CL2, the reception coil CL4, and an insulating film between the transmission coil CL2 and the reception coil CL4 decreases. The smaller the above-described capacitance is, the more improvement of a common mode transient immunity (CMTI) is. Accordingly, according to the semiconductor device DEV1, the CMTI can be improved.

### Second Embodiment

A semiconductor device according to a second embodiment will be described. The semiconductor device according to the second embodiment is described as a semiconductor device DEV2. Here, differences from the semiconductor device DEV1 will be mainly described, and overlapping description thereof is not repeated.

### (Configuration of Semiconductor Device DEV2)

A configuration of the semiconductor device DEV2 will be described below.

The semiconductor device DEV2 includes a semiconductor chip CHP1, a semiconductor chip CHP2, a semiconductor chip CHP3, and a semiconductor chip CHP4. In this regard, the configuration of the semiconductor device DEV2 is in common with the configuration of the semiconductor device DEV1.

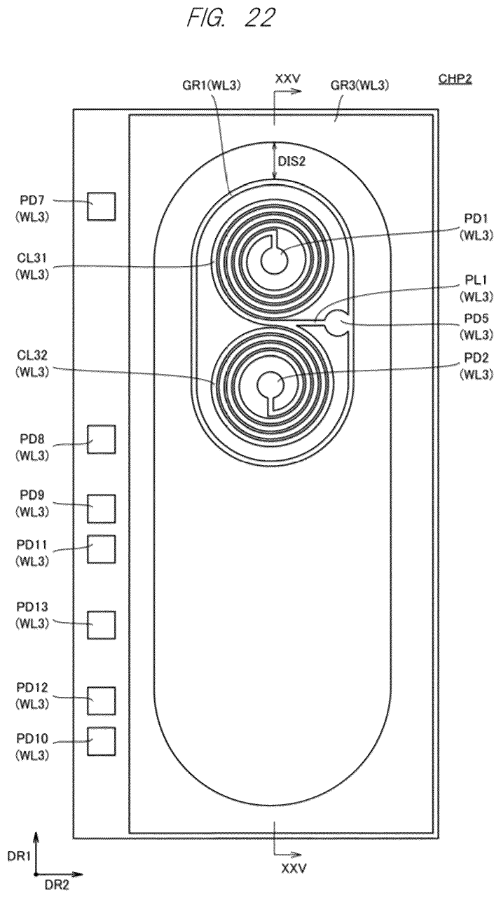

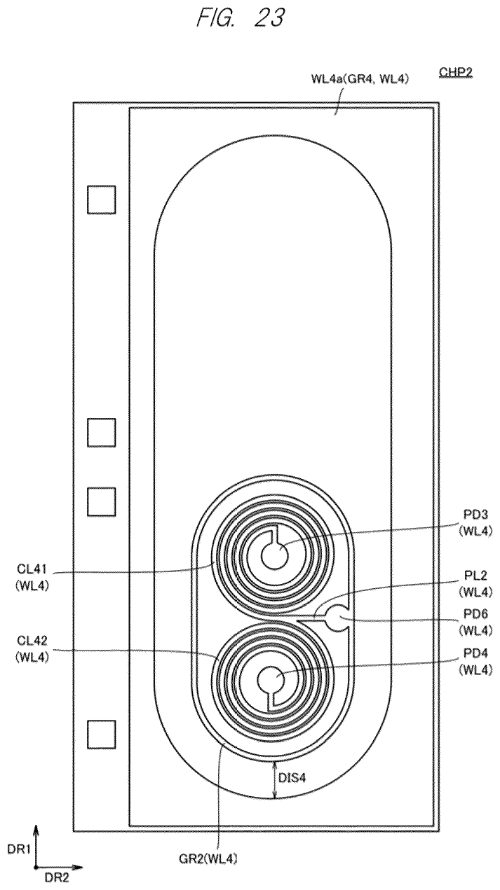

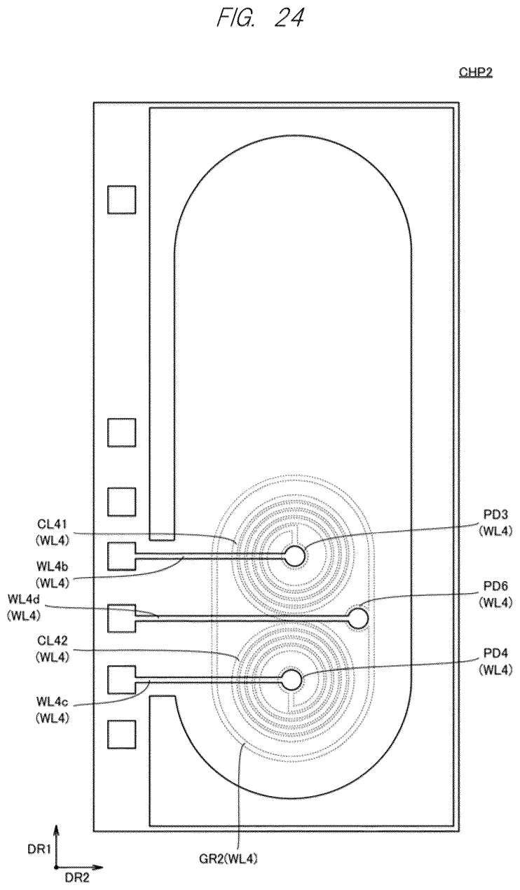

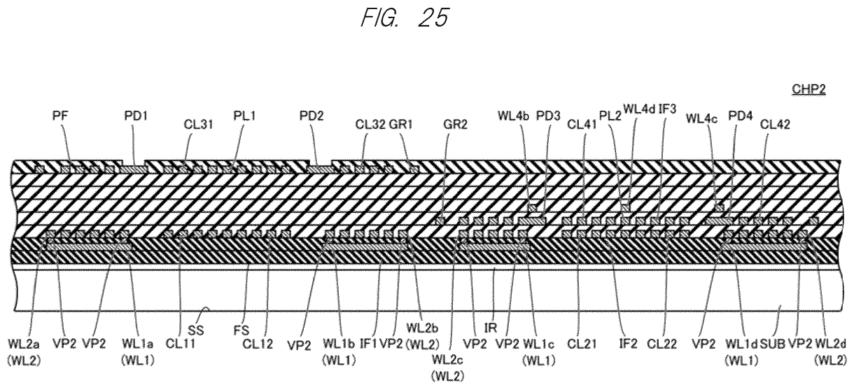

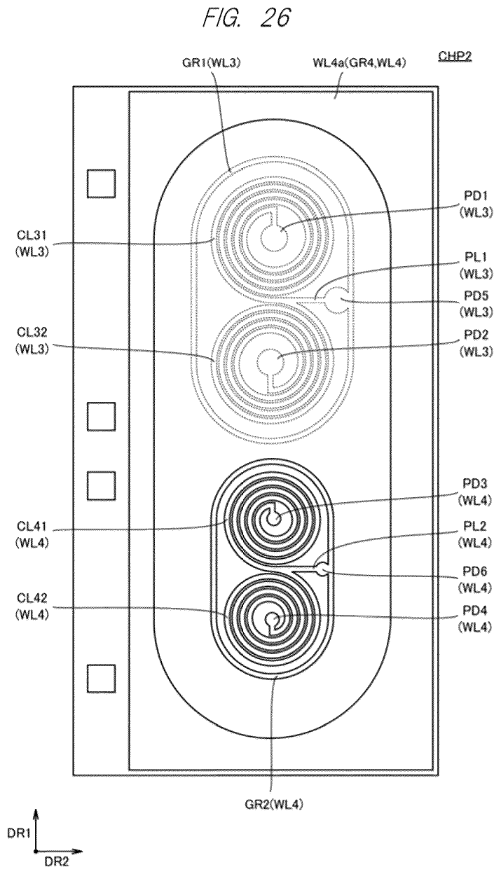

FIG. 22 is a first plan view of the semiconductor chip CHP2 in the semiconductor device DEV2. FIG. 23 is a second plan view of the semiconductor chip CHP2 in the semiconductor device DEV2. FIG. 24 is a third plan view of the semiconductor chip CHP2 in the semiconductor device DEV2. FIG. 25 is a cross-sectional view taken along a line XXV-XXV illustrated in FIG. 22. As illustrated in FIGS. 22 to 25, in the semiconductor chip CHP2 in the semiconductor device DEV2, one wiring layer WL4 includes a reception coil CL4 (a coil CL41 and a coil CL42), a guard ring GR2, a pad PD3, a pad PD4, and a pad PD6. In the semiconductor chip CHP2 in the semiconductor device DEV2, the other wiring layer WL4 includes a wiring WL4a, a wiring WL4b, and a wiring WL4c. In the semiconductor chip CHP2 in the semiconductor device DEV2, a wiring layer WL3 further includes a pad PD11, a pad PD12, and a pad PD13.

From another viewpoint in this regard, when it is assumed that an insulating film IF3 between the transmission coil CL2 and the reception coil CL4 is set as a first insulating film while the collective insulating film IF3 other than the first insulating film is set as a second insulating film, only the first insulating film is interposed between the transmission coil CL2 and the reception coil CL4 while both the first insulating film and the second insulating film are interposed between the transmission coil CL1 and the reception coil CL3. The transformer TR2 is the low-side transformer, and therefore, even if a thickness of the insulating film between the transmission coil CL2 and the reception coil CL4 is small, the withstand voltage between the transmission coil CL2 and the reception coil CL4 can be secured.

In the semiconductor chip CHP2 in the semiconductor device DEV2, the wiring WL4a is a guard ring GR4 that surrounds the guard ring GR2 in plan view. When a shortest distance between the guard ring GR2 and the guard ring GR4 in plan view is described as a distance DIS4, a relationship of “Distance DIS1≤Distance DIS4” is preferably satisfied. The wiring layer WL4 including the reception coil CL4, the guard ring GR2, and the guard ring GR4 is, for example, the wiring layer WL4 functioning as the lowermost layer.

The wiring layer WL4 including the wiring WL4b, the wiring WL4c, and a wiring WL4d is located on, for example, one layer above the wiring layer WL4 including the reception coil CL4, the guard ring GR2, and the guard ring GR4. The wiring WL4b, the wiring WL4c, and the wiring WL4d extend in a second direction DR2 in plan view. One end of the wiring WL4b and one end of the wiring WL4c overlap the pad PD3 and the pad PD4 in plan view. One end of the wiring WL4d overlaps the pad PD6 in plan view. The other end of the wiring WL4b and the other end of the wiring WL4c overlap the pad PD11 and the pad PD12 in plan view. The other end of the wiring WL4d overlaps the pad PD13 in plan view. The pad PD11, the pad PD12, and the Pad PD13 are arranged outside a guard ring GR3 in plan view.

The pad PD11, the pad PD12, and the pad PD13 are respectively electrically connected to the pad PD3, the pad PD4, and the pad PD6 by a via-plug VP3 and the plurality of wiring layers WL4. That is, in the semiconductor chip CHP2 in the semiconductor device DEV2, the pad PD3, the pad PD4, and the pad PD6 are not used as bonding pads for external connection because of not being located on the wiring layer as the uppermost layer, and are pulled up through the wiring layer (the wiring WL4b, the wiring WL4c, and the wiring WL4d) located one layer above to the pad PD11, the pad PD12, and the pad PD13 located on the wiring layer as the uppermost layer. Then, the pad PD11, the pad PD12, and the pad PD13 are used as the bonding pads. Note that the semiconductor chip CHP2 in the semiconductor device DEV2 may not include the guard ring GR2. In these regards, the configuration of the semiconductor device DEV2 differs from the configuration of the semiconductor device DEV1.

### <Effect of Semiconductor Device DEV2>

An effect of the semiconductor device DEV2 will be described below.

In the semiconductor chip CHP2 in the semiconductor device DEV2, the reception coil CL3 and the reception coil CL4 are respectively formed on different wiring layers. Accordingly, in the semiconductor device DEV2, even if the distance DIS1 is small, the distance required to secure the withstand voltage can be secured between the reception coil CL3 and the reception coil CL4, a chip size (more specifically, a dimension in the first direction DR1) of the semiconductor chip CHP2 can be reduced.

### Third Embodiment

A semiconductor device according to a third embodiment will be described. The semiconductor device according to the third embodiment is described as a semiconductor device DEV3. Here, differences from the semiconductor device DEV2 will be mainly described, and overlapping description thereof is not repeated.

### (Configuration of Semiconductor Device DEV3)

A configuration of the semiconductor device DEV3 will be described below.

The semiconductor device DEV3 includes a semiconductor chip CHP1, a semiconductor chip CHP2, a semiconductor chip CHP3, and a semiconductor chip CHP4. In this regard, the configuration of the semiconductor device DEV3 is in common with the configuration of the semiconductor device DEV2.

FIG. 26 is a plan view of the semiconductor chip CHP2 in the semiconductor device DEV3. As illustrated in FIG. 26, in the semiconductor chip CHP2 in the semiconductor device DEV3, a width of a coil CL41 and a width of a coil CL42 in the first direction DR1 are smaller than a width of a coil CL31 and a width of a coil CL32 in the first direction DR1. In the semiconductor chip CHP2 in the semiconductor device DEV3, a width of the coil CL41 and a width of the coil CL42 in the second direction DR2 are also smaller than a width of the coil CL31 and a width of the coil CL32 in the second direction DR2. Similarly, in the semiconductor chip CHP2 in the semiconductor device DEV3, a width of a coil CL21 and a width of a coil CL22 in the first direction DR1 are smaller than a width of a coil CL11 and a width of a coil CL12 in the first direction DR1, and a width of the coil CL21 and a width of the coil CL22 in the second direction DR2 are also smaller than a width of the coil CL11 and a width of the coil CL12 in the second direction DR2.

In the semiconductor chip CHP2 in the semiconductor device DEV3, note that a pad PD3 and a pad PD4 are not used as bonding pads, but their sizes can be reduced. Accordingly, in the semiconductor chip CHP2 in the semiconductor device DEV3, the coil CL41 (the coil CL42) can be made smaller in size than the coil CL31 (the coil CL32) while keeping the number of windings. However, in the semiconductor chip CHP2 in the semiconductor device DEV3, when the number of windings of the coil CL41 (the coil CL42) is made smaller than the number of windings of the coil CL31 (the coil CL32), the respective widths of the coil CL41 (the coil CL42) may be made smaller than the respective widths of the coil CL31 (the coil CL32) in the first direction DR1 and the second direction DR2. In these regards, the configuration of the semiconductor device DEV3 differs from the configuration of the semiconductor device DEV2.

### <Effect of Semiconductor Device DEV3>

An effect of the semiconductor device DEV3 will be described below.

In the semiconductor chip CHP2 in the semiconductor device DEV2, a thickness of the insulating film interposed between the transmission coil CL2 and the reception coil CL4 is smaller than that of the semiconductor chip CHP2 in the semiconductor device DEV1. Accordingly, a capacitance caused by the transmission coil CL2, the reception coil CL4, and the insulating film interposed therebetween increases, and therefore, there is the risk of decrease in the CMTI.

Even in the semiconductor chip CHP2 in the semiconductor device DEV3, a thickness of the insulating film interposed between the transmission coil CL2 and the reception coil CL4 is equal to that of the semiconductor chip CHP2 in the semiconductor device DEV2. However, in the semiconductor chip CHP2 in the semiconductor device DEV3, since respective sizes of the transmission coil CL2 and the reception coil CL4 are small, a capacitance caused by the transmission coil CL2, the reception coil CL4, and the insulating film interposed therebetween decreases. Accordingly, according to the semiconductor device DEV3, the CMTI in the transformer TR2 can be improved while the size of the semiconductor chip CHP2 can be reduced.

### APPENDIX

The embodiments of the present disclose include the following configurations.

### <Appendix 1>

A semiconductor device includes:
a semiconductor substrate;
an insulating film;
a first coil, a second coil, a third coil, a fourth coil,
a fifth coil, a sixth coil, a seventh coil, and an eighth coil; and
a first guard ring and a second guard ring,
the first coil, the second coil, the third coil, and the fourth coil are formed on the semiconductor substrate,
the first coil and the second coil are electrically connected in series with each other,
the third coil and the fourth coil are electrically connected in series with each other,
the fifth coil faces the first coil through the insulating film,
the sixth coil faces the second coil through the insulating film,
the seventh coil faces the third coil through the insulating film,
the eighth coil faces the fourth coil through the insulating film,
the fifth coil and the sixth coil are electrically connected in series with each other,
the seventh coil and the eighth coil are electrically connected in series with each other,
the first guard ring is formed to surround the fifth coil and the sixth coil in plan view,
the second guard ring is formed to surround the seventh coil and the eighth coil in plan view, and
the first guard ring and the second guard ring are adjacent to each other while being spaced apart from each other in plan view.

### <Appendix 2>

In the semiconductor device described in the statement 1,
the first coil and the second coil are arranged side by side in a first direction in plan view,
each of the first guard ring and the second guard ring has a first straight-line portion extending in a second direction perpendicular to the first direction, and
the first straight-line portion of the first guard ring is arranged to face the first straight-line portion of the second guard ring.

### <Appendix 3>

In the semiconductor device described in the statement 2,
the first straight-line portion has a first end and a second end on the opposite side of the first end, and
a remaining portion of each of the first guard ring and the second guard ring extends from the first end to the second end while being curved in plan view.

### <Appendix 4>

In the semiconductor device described in the statement 2,
the first straight-line portion has a first end and a second end on the opposite side of the first end,
each of the first guard ring and the second guard ring further has a second straight-line portion, a third straight-line portion, a first corner portion, a second corner portion, and a circular arc portion,
the second straight-line portion and the third straight-line portion extend in the first direction and face each other in the second direction,
the second straight-line portion has a third end and a fourth end on the opposite side of the third end,
the third straight-line portion has a fifth end and a sixth end on the opposite side of the fifth end,
the first corner portion connects the third end and the first end,
the second corner portion connects the fifth end and the second end,
the first corner portion and the second corner portion extend in a curved shape in plan view, and
the circular arc portion connects the fourth end and the sixth end, and extends in a circular arc shape in plan view.

### <Appendix 5>

In the semiconductor device described in the statement 2, a length of the first straight-line portion in the second direction is equal to or larger than a width of the third coil and a width of the fourth coil therein.

### <Appendix 6>

In the semiconductor device described in the statement 5, the length of the first straight-line portion in the second direction is equal to or larger than 50 μm.

### <Appendix 7>

In the semiconductor device described in the statement 1, the third coil, the fourth coil, the first guard ring, and the second guard ring are formed in the same layer in a cross-sectional view.

### <Appendix 8>

The semiconductor device described in the statement 1 further includes a third guard ring,
the third guard ring is formed to surround the first guard ring and the second guard ring in plan view.

### <Appendix 9>

In the semiconductor device described in the statement 8, a first distance that is a shortest distance between the first guard ring and the second guard ring in plan view is smaller than a second distance that is a shortest distance between the first guard ring and the third guard ring in plan view and a third distance that is a shortest distance between the second guard ring and the third guard ring in plan view.

### <Appendix 10>

In the semiconductor device described in the statement 9,
the first distance is equal to or larger than 15 μm, and
each of the second distance and the third distance is equal to or larger than 50 μm.

### <Appendix 11>

In the semiconductor device described in the statement 8, each of a first voltage applied to the first guard ring and a second voltage applied to the second guard ring is higher than a third voltage applied to the third guard ring.

### <Appendix 12>

In the semiconductor device described in the statement 1,
the first coil and the third coil configure a high-side transformer when being magnetically coupled, and
the second coil and the fourth coil configure a low-side transformer when being magnetically coupled.

### <Appendix 13>

A semiconductor device includes:
a semiconductor substrate;
a first insulating film, a second insulating film, and a third insulating film;
a first wiring layer, a second wiring layer, and a third wiring layer;
a first coil, a second coil, a third coil, a fourth coil, a fifth coil, a sixth coil, a seventh coil, and an eighth coil; and
a first guard ring and a second guard ring,
the first insulating film is formed on the semiconductor substrate,
the first wiring layer is formed on the first insulating film,
the second insulating film is formed on the first insulating film to cover the first wiring layer,
the second wiring layer is arranged on the second insulating film,
the third insulating film is formed on the second insulating film to cover the second wiring layer,
the third wiring layer is formed on the third insulating film,
the first coil, the second coil, the third coil, and the fourth coil are formed in the first wiring layer,
the fifth coil and the sixth coil are formed in the third wiring layer,
the seventh coil and the eighth coil are formed in the second wiring layer,
the first coil and the second coil respectively face the fifth coil and the sixth coil through the second insulating film and the third insulating film,
the third coil and the fourth coil respectively face the seventh coil and the eighth coil through the second insulating film,
the first guard ring is formed to surround the fifth coil and the sixth coil in plan view,
the second guard ring is formed to surround the seventh coil and the eighth coil in plan view, and
the first guard ring and the second guard ring are adjacent to each other while being spaced apart from each other in plan view.

### <Appendix 14>

A semiconductor device includes:
a first semiconductor chip;
a second semiconductor chip;
a third semiconductor chip; and
a fourth semiconductor chip,
the first semiconductor chip includes a first transmission circuit and a second transmission circuit,
the second semiconductor chip includes a high-side first transformer and a low-side second transformer,
the third semiconductor chip includes a first reception circuit,
the fourth semiconductor chip includes a second reception circuit,
a signal transmitted by the first transmission circuit is transmitted in a pulse communication mode to the first reception circuit via the first transformer,
a signal transmitted by the second transmission circuit is transmitted in a pulse communication mode to the second reception circuit via the second transformer,
the third semiconductor chip includes a semiconductor substrate, an insulating film, a first coil, a second coil, a third coil, a fourth coil, a first guard ring and a second guard ring,
the first coil and the second coil are formed on the semiconductor substrate,
the third coil faces the first coil through the insulating film,
the fourth coil faces the second coil through the insulating film,
the first coil and the third coil configure the first transformer when being magnetically coupled,
the second coil and the fourth coil configure the second transformer when being magnetically coupled, and
the first guard ring is formed to surround the third coil in plan view,
the second guard ring is formed to surround the fourth coil in plan view, and
the first guard ring and the second guard ring are adjacent to each other while being spaced apart from each other in plan view.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a semiconductor substrate;
an insulating film;
a first coil, a second coil, a third coil and a fourth coil; and
a first guard ring and a second guard ring;
wherein the first coil and the second coil are formed on the semiconductor substrate,
wherein the third coil faces the first coil through the insulating film,
wherein the fourth coil faces the second coil through the insulating film,
wherein the first guard ring is formed to surround the third coil in plan view,
wherein the second guard ring is formed to surround the fourth coil in plan view, and
wherein the first guard ring and the second guard ring are adjacent to each other while being spaced apart from each other in plan view.

2. The semiconductor device according to claim 1,
wherein the first coil and the second coil are arranged side by side in a first direction in plan view,
wherein each of the first guard ring and the second guard ring has a first straight-line portion extending in a second direction perpendicular to the first direction, and
wherein the first straight-line portion of the first guard ring is arranged to face the first straight-line portion of the second guard ring.

3. The semiconductor device according to claim 2,
wherein the first straight-line portion has a first end and a second end on the opposite side of the first end, and
wherein a remaining portion of each of the first guard ring and the second guard ring extends from the first end to the second end while being curved in plan view.

4. The semiconductor device according to claim 2,
wherein the first straight-line portion has a first end and a second end on the opposite side of the first end,
wherein each of the first guard ring and the second guard ring further has a second straight-line portion, a third straight-line portion, a first corner portion, a second corner portion, and a circular arc portion,
wherein the second straight-line portion and the third straight-line portion extend in the first direction and face each other in the second direction,
wherein the second straight-line portion has a third end and a fourth end on the opposite side of the third end,
wherein the third straight-line portion has a fifth end and a sixth end on the opposite side of the fifth end,
wherein the first corner portion connects the third end and the first end,
wherein the second corner portion connects the fifth end and the second end,
wherein the first corner portion and the second corner portion extend in a curved shape in plan view, and
wherein the circular arc portion connects the fourth end and the sixth end, and extends in a circular arc shape in plan view.

5. The semiconductor device according to claim 2,
wherein in the second direction, a length of the first straight-line portion is equal to or larger than a width of the third coil and a width of the fourth coil.

6. The semiconductor device according to claim 5,
wherein the length of the first straight-line portion in the second direction is equal to or larger than 50 μm.

7. The semiconductor device according to claim 1,
wherein the third coil, the fourth coil, the first guard ring, and the second guard ring are formed in the same layer in a cross-sectional view.

8. The semiconductor device according to claim 1 further comprising:
a third guard ring,
wherein the third guard ring is formed to surround the first guard ring and the second guard ring in plan view.

9. The semiconductor device according to claim 8,
wherein a first distance that is a shortest distance between the first guard ring and the second guard ring in plan view is smaller than a second distance that is a shortest distance between the first guard ring and the third guard ring in plan view and a third distance that is a shortest distance between the second guard ring and the third guard ring in plan view.

10. The semiconductor device according to claim 9,
wherein the first distance is equal to or larger than 15 μm, and
wherein each of the second distance and the third distance is equal to or larger than 50 μm.

11. The semiconductor device according to claim 8,
wherein each of a first voltage applied to the first guard ring and a second voltage applied to the second guard ring is higher than a third voltage applied to the third guard ring.

12. The semiconductor device according to claim 1,
wherein the first coil and the third coil configure a high-side transformer when being magnetically coupled, and
wherein the second coil and the fourth coil configure a low-side transformer when being magnetically coupled.

13. A semiconductor device comprising:
a semiconductor substrate;
a first insulating film, a second insulating film, and a third insulating film;
a first wiring layer, a second wiring layer, and a third wiring layer;
a first coil, a second coil, a third coil, and a fourth coil; and
a first guard ring and a second guard ring,
wherein the first insulating film is formed on the semiconductor substrate,
wherein the first wiring layer is formed on the first insulating film,
wherein the second insulating film is formed on the first insulating film to cover the first wiring layer,
wherein the second wiring layer is arranged on the second insulating film,
wherein the third insulating film is formed on the second insulating film to cover the second wiring layer,
wherein the third wiring layer is formed on the third insulating film,
wherein the first coil and the second coil are formed in the first wiring layer,
wherein the third coil is formed in the third wiring layer,
wherein the fourth coil is formed in the second wiring layer,
wherein the first coil and the third coil face each other through the second insulating film and the third insulating film,
wherein the second coil and the fourth coil face each other through the second insulating film,
wherein the first guard ring is formed to surround the third coil in plan view,
wherein the second guard ring is formed to surround the fourth coil in plan view, and
wherein the first guard ring and the second guard ring are adjacent to each other while being spaced apart from each other in plan view.

14. The semiconductor device according to claim 13,
wherein the first guard ring is formed in the third wiring layer, and
wherein the second guard ring is formed in the second wiring layer.

15. The semiconductor device according to claim 13 further comprising:
a third guard ring,
wherein the third guard ring is formed to surround the first guard ring and the second guard ring in plan view.

16. The semiconductor device according to claim 15,
wherein a first distance that is a shortest distance between the first guard ring and the second guard ring in plan view is smaller than a second distance that is a shortest distance between the first guard ring and the third guard ring in plan view and a third distance that is a shortest distance between the second guard ring and the third guard ring in plan view.

17. The semiconductor device according to claim 16,
wherein the first distance is equal to or larger than 15 μm, and
wherein each of the second distance and the third distance is equal to or larger than 50 μm.

18. The semiconductor device according to claim 13,
wherein the first coil and the second coil are arranged side by side in a first direction in plan view,
wherein in the first direction, a width of the second coil and a width of the fourth coil are smaller than a width of the first coil and a width of the third coil, and
wherein in a second direction perpendicular to the first direction, a width of the second coil and a width of the fourth coil in a second direction perpendicular to the first direction are smaller than a width of the first coil and a width of the third coil therein.

19. The semiconductor device according to claim 13,
wherein the number of windings of the second coil and the number of windings of the fourth coil are smaller than the number of windings of the first coil and the number of windings of the third coil.

20. A semiconductor device comprising:
a first semiconductor chip;
a second semiconductor chip;
a third semiconductor chip; and
a fourth semiconductor chip,
wherein the first semiconductor chip includes a first transmission circuit and a second transmission circuit,
wherein the second semiconductor chip includes a high-side first transformer and a low-side second transformer,
wherein the third semiconductor chip includes a first reception circuit,
wherein the fourth semiconductor chip includes a second reception circuit,
wherein a signal transmitted by the first transmission circuit is transmitted to the first reception circuit via the first transformer,
wherein a signal transmitted by the second transmission circuit is transmitted to the second reception circuit via the second transformer,
wherein the third semiconductor chip includes a semiconductor substrate, an insulating film, a first coil, a second coil, a third coil, a fourth coil, a first guard ring and a second guard ring,
wherein the first coil and the second coil are formed on the semiconductor substrate,
wherein the third coil faces the first coil through the insulating film,
wherein the fourth coil faces the second coil through the insulating film,
wherein the first coil and the third coil configure the first transformer when being magnetically coupled,
wherein the second coil and the fourth coil configure the second transformer when being magnetically coupled, and
wherein the first guard ring is formed to surround the third coil in plan view,
wherein the second guard ring is formed to surround the fourth coil in plan view, and
wherein the first guard ring and the second guard ring are adjacent to each other while being spaced apart from each other in plan view.
